(19) United States
(12) Patent Application Publication
(10) Pub. No.: US 2024/0407180 A1
(43) Pub. Date: Dec. 5, 2024

(54) SINGLE PACKAGE DATA STORAGE DEVICE

(71) Applicant: Western Digital Technologies, Inc., San Jose, CA (US)

(72) Inventors: Fei Wang, Shanghai (CN); Tan Chong Un, Shanghai (CN); Hui Xu, Shanghai (CN); Teng Sun, Shanghai (CN); Gang Liu, Shanghai (CN)

(21) Appl. No.: 18/361,081

(22) Filed: Jul. 28, 2023

Related U.S. Application Data
(60) Provisional application No. 63/505,639, filed on Jun. 1, 2023.

(51) Int. Cl. H10B 80/00; H01L 23/00; H01L 23/538; H01L 25/16

(52) U.S. Cl. CPC H10B 80/00; H01L 23/5386; H01L 24/13; H01L 24/16; H01L 24/81; H01L 25/16; H01L 24/48; H01L 2224/13147; H01L 2224/16225; H01L 2224/48091; H01L 2224/48105; H01L 2224/48145; H01L 2224/48225; H01L 2224/81815

(57) ABSTRACT

A data storage device includes a controller, one or more memory devices and one or more passive components encapsulated in a single package. The controller, the memory devices and the passive components are directly mounted to a printed circuit board (PCB) of the data storage device. A position of the controller with respect to the one or more memory devices enables the data storage device to use shorter signal traces. Shorter signal traces leads to improved read and/or write speeds of the data storage device along with other benefits.

### CROSS-REFERENCE TO RELATED APPLICATIONS

The present application claims priority to U.S. Provisional Application 63/505,639 entitled “SINGLE PACKAGE DATA STORAGE DEVICE”, filed Jun. 1, 2023, the entire disclosure of which is hereby incorporated by reference in its entirety.

### BACKGROUND

An increasing number of electronic devices use various data storage devices to process and store data. In particular, solid-state drives (SSDs) are becoming increasing popular. For example, when compared with traditional hard disk drives (HDDs), SDDs have better read and write speeds, are more reliable and are more compact.

However, as the demand for SDDs increases, so do the demands for increased storage capacity and faster speeds. As higher capacity and faster SSDs are produced, the SSD becomes more complex. The more complex the SSD, the more expensive the manufacturing process becomes in terms of both time and cost.

For example, higher capacity SSDs typically require higher capacity memory devices. In order to accommodate higher capacity memory devices, a printed circuit board (PCB) of the SSD typically needs to have additional layers. As more layers are added to the PCB, additional vias are also added to the PCB and trace routing becomes more complex. Additionally, each component of the SSD (e.g., a controller and each of the memory devices) may need to be separately tested.

Accordingly, it would be beneficial for a data storage device, such as a SSD, to have higher capacity and higher speeds without increasing the complexity of manufacturing.

### SUMMARY

The present application describes a data storage device that has a controller, one or more memory devices and one or more passive components integrated within a single package. The controller, the one or more memory devices and the one or more passive components are mounted directly to a surface of a printed circuit board (PCB) of the data storage device. The one or more memory devices are communicatively coupled to the controller using a signal trace associated with the PCB. Likewise, the controller is communicatively coupled to a connector or an interface of the PCB using additional signal traces associated with the PCB. A molding compound is used to encapsulate the controller, the one or more memory devices and the one or more passive components.

Because the controller and the one or more memory devices are mounted directly to the surface of the same PCB, a need for ball grid arrays (BGAs) and solder balls is eliminated. Additionally, the layout of the controller with respect to the one or more memory devices improves trace routing between the controller and the one or more memory devices. For example, the layout of the controller with respect to the one or more memory devices shortens signal/communication paths when compared with current solutions. Shorter signal/communication paths lead to improved read and/or write speeds of the data storage device.

Accordingly, the present application describes a data storage device that includes a printed circuit board (PCB). A controller is mounted directly to a surface of the PCB. A memory device is also mounted directly to the surface of the PCB and is communicatively coupled to a signal trace associated with the PCB. The signal trace establishes a communication path between the memory device and the controller. A cover encapsulates the controller and the memory device.

A method for assembling a data storage device is also described. In an example, the method includes coupling a controller to a surface of a printed circuit board (PCB). One or more passive components are also coupled to the surface of the PCB. A reflow soldering process is performed to secure the controller and the one or more passive components to the surface of the PCB. A memory device is provided on the surface of the PCB. The memory device is electrically coupled to a signal trace associated with the PCB. A single cover is formed around the controller, the one or more passive components and the memory device.

The present application also describes a data storage device. In an example, the data storage device includes a printed circuit board (PCB). A first storage means mounted directly to a surface of the PCB. The first storage means is communicatively coupled to a first signal means associated with the PCB. A second storage means is also mounted directly to the surface of the PCB. The second storage means is communicatively coupled to a second signal means associated with the PCB. A controller means is mounted directly to the surface of the PCB between the first storage means and the second storage means. The controller means is communicatively coupled to the first storage means using the first signal means and is also communicatively coupled to the second storage means using the second signal means. A covering means encapsulates the first storage means, the second storage means and the controller means.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates an existing data storage device according to an example.

FIG. 2 illustrates a data storage device having a memory device and a controller integrated within a single package according to an example.

FIG. 3A-FIG. 3E illustrate a method or a process for manufacturing a data storage device according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

The present application describes a data storage device in which a controller, one or more memory devices and one or more passive components are encapsulated in a single package. Unlike current data storage devices in which the controller and the memory devices are packaged separately and are coupled to a printed circuit board (PCB) of the data storage device using a ball grid array (BGA), the controller, the one or more memory devices and the one or more passive components of the data storage device of the present disclosure are directly mounted to the PCB.

Additionally, a layout of the controller with respect to the one or more memory devices improves trace routing between the controller and the one or more memory devices when compared with current data storage devices. For example, the layout of the controller with respect to the one or more memory devices shortens signal/communication paths when compared with current solutions. Shorter signal/communication paths lead to improved read and/or write speeds of the data storage device.

In addition to the benefits listed above, shorter signal/communication paths may also provide additional technical benefits including, but not limited to, a reduction in resistance, better signal transmission between the controller and the memory devices and/or lowering the overall operating temperature of the data storage device.

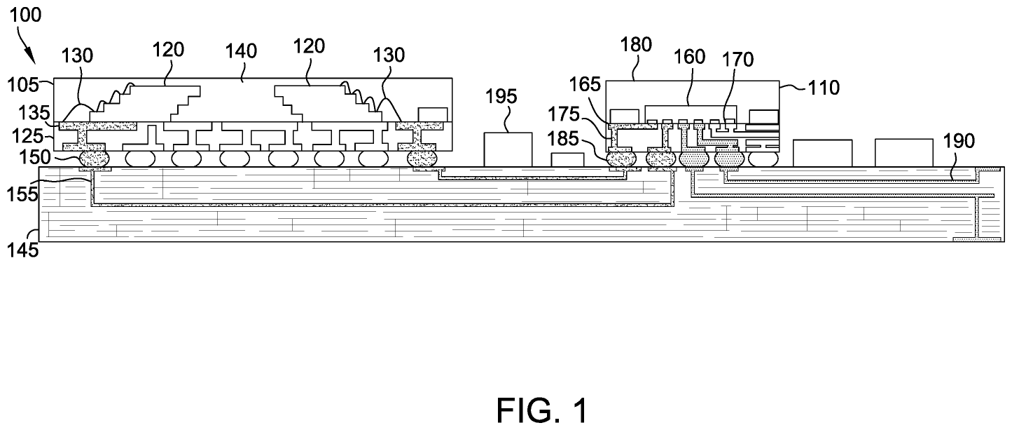

These benefits, along with other examples, will be shown and described in greater detail with respect to FIG. 1-FIG. 3E.

FIG. 1 illustrates an existing data storage device 100 according to an example. The data storage device 100 may be a solid-state drive (SSD) or an enterprise solid-state drive (eSSD). In the example shown in FIG. 1, the data storage device 100 has a memory device package 105 that is separate from a controller package 110.

The memory device package 105 includes one or more NAND die stacks 120 mounted to a substrate 125. Bond wires 130 are used to communicatively couple the NAND die stacks 120 to a signal trace 135 provided within the substrate 125. The one or more NAND die stacks 120 and the bond wires 130 may be encapsulated by a cover 140. In an example, the cover 140 is a molding compound or other such material.

The memory device package 105 is mounted to a printed circuit board (PCB) 145 of the data storage device 100. In the example shown, the memory device package 105 is mounted to the PCB 145 using solder balls that are part of, or otherwise form, a ball grid array (BGA) 150 of the memory device package 105. One or more of the solder balls of the BGA 150 of the memory device package 105 is communicatively coupled to a first trace 155 (or a first set of traces) provided within the PCB 145.

The controller device package 110 includes a controller 160. The controller 160 is mounted to a substrate 165 of the controller device package 110 using one or more bump pads and/or copper pillars 170. The one or more bump pads and/or copper pillars 170 are communicatively coupled to respective signal traces 175 within the substrate 165 of the controller device package 110. The controller 160 and the one or more bump pads and/or copper pillars 170 are encapsulated by a cover 180. In an example, the cover 180 is a molding compound or other such material.

The controller device package 110 is mounted to the PCB 145 of the data storage device 100 using solder balls that are part of, or otherwise form, a BGA 185 associated with the controller device package 110. One or more of the solder balls are communicatively coupled to a second trace 190 (or a second set of traces) provided within the PCB 145.

For example, a first set of solder balls of the BGA 185 associated with the controller device package 110 are communicatively coupled to the first trace 155 (or the first set of traces). As such, the first trace 155 is used to communicatively couple the one or more NAND die stacks 120 of the memory device package 105 to the controller 160 of the controller package 110.

For example and as shown by a first type of shading in FIG. 1, the NAND die stacks 120 are coupled (via bond wires 130) to the signal trace 135 provided in the substrate 125 of the memory device package 105. The signal trace 135 is electrically coupled to one or more solder balls of the BGA 150 associated with the memory device package 105. The one or more solder balls of the BGA 150 associated with the memory device package 105 are also communicatively coupled to the first signal trace 155 (or the first set of signal traces) provided within the PCB 145 of the data storage device 100.

The first trace 155 extends through the PCB 145 of the data storage device 100 and is communicatively coupled to one or more solder balls of the BGA 185 associated with the controller device package 110. As previously indicated, the solder balls of the BGA 185 associated with the controller device package 110 are communicatively coupled to signal traces 175 within the substrate 165 of the controller device package 110. The signal traces 175 are also communicatively coupled to the controller 160 of the controller device package 110.

A second set of solder balls of the BGA 185 associated with the controller device package 110 are communicatively coupled to a second trace 190 (or a second set of traces) associated with the PCB 145. In this example, the second trace 190 is used to couple the controller to an interface (e.g., a connector) of the data storage device 100.

One or more passive components 195 (e.g., capacitors, resistors) may also be mounted on the surface of the PCB 145 of the data storage device 100. As shown, the one or more passive components 195 are not included within the memory device package 105 or the controller package 110.

The data storage device 100 shown in FIG. 1 requires a PCB 145 that has many layers. Some of the layers are required due to the memory device package 105 being separate from the controller package 110. For example, because the memory device package 105 and the controller package 110 are associated with different BGAs, additional layers, vias and traces are required. As additional layers, traces and vias are added, trace routing becomes more difficult and complex.

Another drawback of the data storage device 100 is that the memory device package 105 is typically tested separately from the controller device package 110. Separate testing processes may delay or slow production of the data storage device 100.

Use of solder balls and/or BGAs is another drawback of the data storage device 100. For example, whenever solder balls are used, there is a risk that air pockets (e.g., solder voiding) may be formed within the solder balls during a reflow soldering process. Solder voiding decreases the reliability of the connections between the various components, which can negatively affect the performance of the data storage device 100.

Another drawback of the data storage device 100 is an overall length of the traces within the PCB 145. As the length of the traces increases, resistance increases, signal transmission degrades and an operating temperature of the data storage device may increase. All of these factors may negatively impact the performance of the data storage device 100.

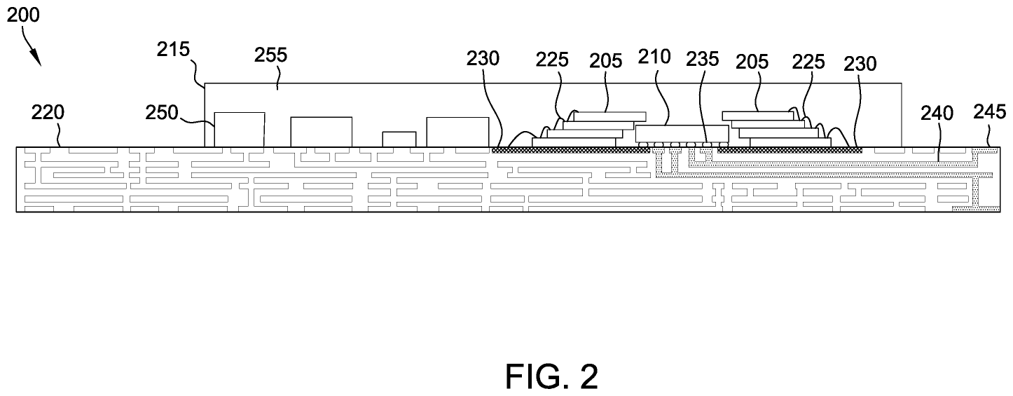

FIG. 2 illustrates a data storage device 200 having a memory device 205 and a controller 210 integrated within a single package 215 according to an example. The data storage device 200 may be an SSD, an eSSD or another data storage device. As will be explained, the data storage device 200 addresses the various drawbacks of the data storage device 100 shown and described above with respect to FIG. 1.

As previously indicated, the data storage device 200 includes a memory device 205. In the example shown in FIG. 2, the data storage device 200 includes two memory devices 205 that are positioned on either side of the controller 210. In an example, each memory device 205 may be a stack of NAND memory dies. Although a stack of NAND memory dies are specifically mentioned, the memory device 205 may be any volatile or non-volatile memory device.

Each memory device 205 is coupled to a surface of a printed circuit board (PCB) 220 of the data storage device 200. For example, each memory device 205 is directly coupled to the surface of the PCB 220. The memory device 205 may be coupled to the surface of the PCB 220 using any known surface mounting technique. However, the memory device 205 is coupled to the surface of the PCB 200 without using a BGA, a separate substrate, traces, etc. This is unlike the memory device 120 of the data storage device 100 of FIG. 1 that requires a separate substrate 125, signal traces 135 and a BGA 150.

In an example, a bond wire 225 communicatively couples the memory device 205 to a first signal trace 230 (or a first set of signal traces) associated with the PCB 220. As shown in FIG. 2, the first signal trace 230 (illustrated by a first type of shading) electrically and/or communicatively couples the memory device 205 to the controller 210. For example, the first signal trace 230 may electrically and/or communicatively couple the memory device 205 to one or more connection points (e.g., a pad and/or pillar used to surface mount or otherwise couple the controller 210 to the PCB 220) associated with the controller 210.

Based on the position of each memory device 205 on the PCB 220 with respect to the position of the controller 210, the first signal trace 230 is substantially shorter when compared with the first trace 155 provided within the PCB 145 of the data storage device 100 shown and described with respect to FIG. 1. Shorter communication paths between the controller 210 and the memory devices 205 improves read and/or write speeds of the data storage device 200, causes a reduction in resistance, enables better signal transmission between the controller 210 and the memory devices 205 and/or lowers the overall operating temperature of the data storage device 200.

The controller 210 is also directly mounted to the surface of the PCB 220. In an example, the controller 210 is directly mounted to the surface of the PCB 220 using a surface mounting technique and/or a reflow soldering process. For example, one or more pads (e.g., bump pads) and/or pillars 235 (e.g., copper pillars) may be used to surface mount the controller 210 to the PCB 220. Although pads and/or pillars 235 are specifically mentioned, other surface mounting techniques may be used. However, in this example, the controller 210 is coupled to the surface of the PCB 220 without using a BGA, a separate substrate, traces, etc., unlike the controller 160 of the data storage device 100 of FIG. 1 that requires a separate substrate 165, signal traces 175 and a BGA 185.

In an example, a first subset of the pads and/or pillars 235 are used to electrically and/or communicatively couple the controller 210 to the memory device 205. A second subset of pads and/or pillars 235 may be electrically and/or communicatively coupled to a second signal trace 240 (or a second set of signal traces) associated with the PCB 220. The second signal trace 240 may be used to communicatively couple the controller 210 to an interface 245 of the data storage device 200. In an example, the interface 245 may be pins of a connector (e.g., an edge connector) that extends from the PCB 220. For illustration purposes, the connection path between the controller 210, the second signal trace 240 and the interface 245 is shown in a second type of shading (e.g., when compared with the first type of shading shown with respect to the first signal trace 230).

In an example, and due to the position of the controller 210 on the PCB 220, a length of the second signal trace 240 (or the second set of signal traces) may be shorter than a length of the second trace 190 associated with the PCB 145 of the data storage device 100 shown and described with respect to FIG. 1. In an example, shorter communication paths between the controller 210 and the interface 245 improves read and/or write speeds of the data storage device 200, causes a reduction in resistance, enables better signal transmission between the controller 210 and the interface 245 and/or lowers the overall operating temperature of the data storage device 200.

The data storage device 200 also includes one or more passive components 250. The one or more passive components 250 may be capacitors, resistors or other electronic components. The one or more passive components 250 are also mounted on the surface of the PCB 220. In an example, the one or more passive components 250 are mounted to the surface of the PCB 220 using a reflow soldering process. The reflow soldering process that is used to mount the one or more passive components 250 on the PCB 220 may be the same reflow soldering process that is used to electrically and/or communicatively couple the controller 210 to the PCB 220.

The data storage device 200 also includes a cover 255. In an example, the cover is a molding compound or other material. The molding compound may be any suitable molding material (e.g., an epoxy molding compound). In an example, the molding material may have heat dissipation properties. The cover 255 may encapsulate the memory devices 205, the controller 210, the bond wires 225 and/or the one or more passive components 250.

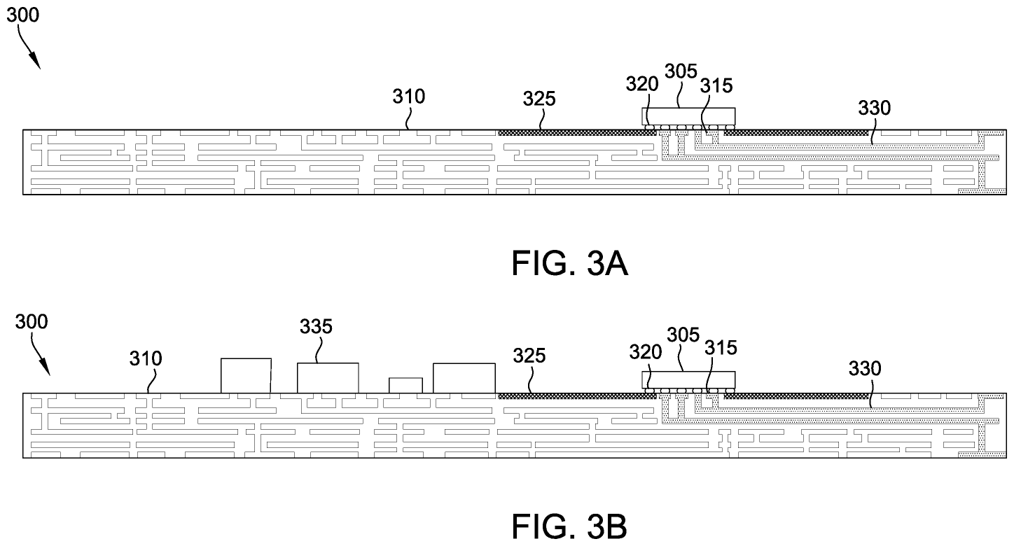

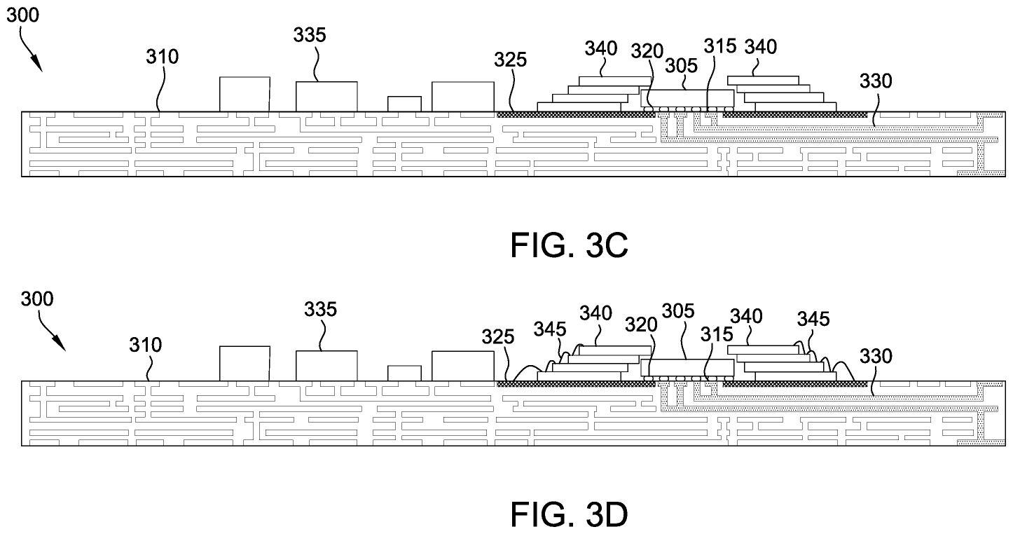

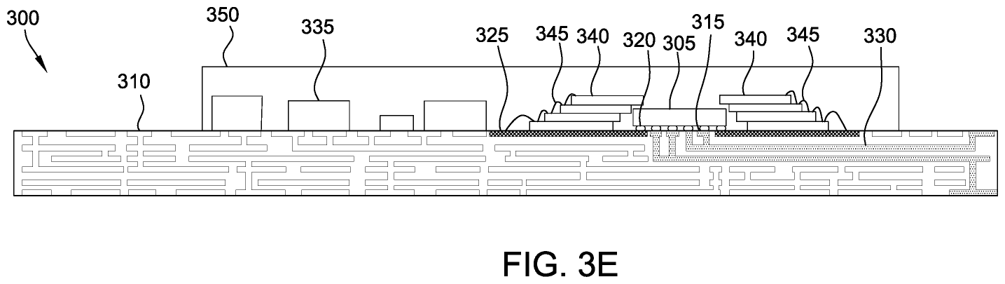

FIG. 3A-FIG. 3E illustrate a method or a process 300 for manufacturing a data storage device according to an example. In an example, the method or process 300 shown and described with respect to FIG. 3A-FIG. 3E may be used to manufacture the data storage device 200 shown and described with respect to FIG. 2.

As shown in FIG. 3A, the method or the process 300 may begin when a controller 305 is directly mounted to a surface of a printed circuit board (PCB) 310. In an example, the controller 305 is directly mounted to the surface of the PCB 310 using one or more pads 315 (e.g., bump pads) and/or one or more pillars 320 (e.g., copper pillars).

In an example, the one or more pads 315 and/or the one or more pillars 320 are used to establish communication paths between a first signal trace 325 (or a first set of signal traces) provided in or otherwise associated with the PCB 310 and a second signal trace 330 (or a second set of signal traces) provided in or otherwise associated with the PCB 310. For example, a first subset of pads 315 and/or pillars 320 may be used to establish a first communication path between the controller 305 and the first signal trace 325 (or the first set of signal traces) and a second subset of pads 315 and/or pillars 320 may be used to establish a second communication path between the controller 305 and the second signal trace 330 (or the second set of signal traces).

FIG. 3B illustrates another step in the method or the process 300 in which one or more passive components 335 are surface mounted to the PCB 310. The one or more passive components may be surface mounted to the PCB using any suitable mounting technique. Once the passive components 335 and the controller have been surface mounted to the PCB 310, a reflow soldering process may be used to secure the controller 305 and the one or more passive components to the PCB 310. In an example, the one or more passive components 335 may be mounted to the PCB 310 before or after the controller 305.

FIG. 3C illustrates yet another step in the method or the process 300. In this example, one or more memory devices 340 are directly coupled to the surface of the PCB 310. In an example one memory device 340 may be provided on a first side of the controller 305 while another memory device 340 is positioned on a second side of the controller 305. Although two memory devices 340 are shown, additional memory devices 340 may be surface mounted to the PCB 310 on various sides of the controller 320.

As shown in FIG. 3D, the process 300 continues when bond wires 345 are used to electrically couple each memory device 340 to the PCB 310. For example, bond wires 345 are used to electrically and/or communicatively couple each memory device 340 to the first signal trace 325 (or the first set of signal traces) associated with the PCB 310.

As shown in FIG. 3E, the process 300 continues by providing a cover 350 on the data storage device. In an example, the cover 350 is a molding compound that surrounds or encapsulates the controller 305, the memory devices 340, the bond wires 345 and the one or more passive components 335.

Based on the various examples described herein, examples of the present disclosure describe a data storage device, comprising: a printed circuit board (PCB); a controller mounted directly to a surface of the PCB; a memory device mounted directly to the surface of the PCB and communicatively coupled to a signal trace associated with the PCB, the signal trace establishing a communication path between the memory device and the controller; and a cover encapsulating the controller and the memory device. In an example, the data storage device further includes one or more passive components mounted directly to the surface of the PCB. In an example the one or more passive components are encapsulated by the cover. In an example, the one or more passive components are mounted directly to the surface of the PCB using a reflow soldering process. In an example, the controller is mounted directly to the surface of the PCB using a reflow soldering process. In an example, the cover is a molding compound. In an example, the controller is communicatively coupled to an interface of the data storage device using another signal trace associated with the PCB. In an example, the memory device is a stack of NAND memory dies. In an example, the memory device is a first memory device and the data storage device further comprises a second memory device mounted directly to the surface of the PCB such that the first memory device is positioned on a first side of the controller and the second memory device is positioned on a second side of the controller.

In an example, the present application also describes a method for assembling a data storage device, comprising: coupling a controller to a surface of a printed circuit board (PCB); coupling one or more passive components to the surface of the PCB; performing a reflow soldering process to secure the controller and the one or more passive components to the surface of the PCB; coupling a memory device to the surface of the PCB; electrically coupling the memory device to a signal trace associated with the PCB; and encapsulating the controller, the one or more passive components and the memory device with a single cover. In an example, the signal trace communicatively couples the memory device to the controller. In an example, the single cover is comprised of a molding compound. In an example, the controller is coupled to the surface of the PCB using one or more bump pads and one or more copper pillars. In an example, the method includes communicatively coupling the controller to a connection interface provided on the surface of the PCB. In an example, the memory device is a stack of NAND memory dies.

In yet another example, the present application describes a data storage device, comprising: a printed circuit board (PCB); a first storage means mounted directly to a surface of the PCB and communicatively coupled to a first signal means associated with the PCB; a second storage means mounted directly to the surface of the PCB and communicatively coupled to a second signal means associated with the PCB; a controller means mounted directly to the surface of the PCB between the first storage means and the second storage means and being communicatively coupled to the first storage means using the first signal means and being communicatively coupled to the second storage means using the second signal means; and a covering means encapsulating the first storage means, the second storage means and the controller means. In an example, the first storage means and the second storage means are comprised of NAND memory dies. In an example, the data storage device also includes one or more electronic components coupled to the surface of the PCB, wherein the one or more components are encapsulated by the covering means. In an example, the controller means is communicatively coupled to a connection means of the data storage device. In an example, the controller means is mounted directly to the surface of the PCB using a reflow soldering process.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features are intended to be selectively rearranged, included or omitted to produce various embodiments with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A data storage device, comprising:
a printed circuit board (PCB);
a controller mounted directly to a surface of the PCB;
a memory device mounted directly to the surface of the PCB and communicatively coupled to a signal trace associated with the PCB, the signal trace establishing a communication path between the memory device and the controller; and
a cover encapsulating the controller and the memory device.

2. The data storage device of claim 1, further comprising one or more passive components mounted directly to the surface of the PCB.

3. The data storage device of claim 2, wherein the one or more passive components are encapsulated by the cover.

4. The data storage device of claim 2, wherein the one or more passive components are mounted directly to the surface of the PCB using a reflow soldering process.

5. The data storage device of claim 1, wherein the controller is mounted directly to the surface of the PCB using a reflow soldering process.

6. The data storage device of claim 1, wherein the cover is a molding compound.

7. The data storage device of claim 1, wherein the controller is communicatively coupled to an interface of the data storage device using another signal trace associated with the PCB.

8. The data storage device of claim 1, wherein the memory device is a stack of NAND memory dies.

9. The data storage device of claim 1, wherein the memory device is a first memory device and wherein the data storage device further comprises a second memory device mounted directly to the surface of the PCB such that the first memory device is positioned on a first side of the controller and the second memory device is positioned on a second side of the controller.

10. A method for assembling a data storage device, comprising:
coupling a controller to a surface of a printed circuit board (PCB);
coupling one or more passive components to the surface of the PCB;
performing a reflow soldering process to secure the controller and the one or more passive components to the surface of the PCB;
coupling a memory device to the surface of the PCB;
electrically coupling the memory device to a signal trace associated with the PCB; and
encapsulating the controller, the one or more passive components and the memory device with a single cover.

11. The method of claim 10, wherein the signal trace communicatively couples the memory device to the controller.

12. The method of claim 10, wherein the single cover is comprised of a molding compound.

13. The method of claim 10, wherein the controller is coupled to the surface of the PCB using one or more bump pads and one or more copper pillars.

14. The method of claim 10, further comprising communicatively coupling the controller to a connection interface provided on the surface of the PCB.

15. The method of claim 10, wherein the memory device is a stack of NAND memory dies.

16. A data storage device, comprising:
a printed circuit board (PCB);
a first storage means mounted directly to a surface of the PCB and communicatively coupled to a first signal means associated with the PCB;
a second storage means mounted directly to the surface of the PCB and communicatively coupled to a second signal means associated with the PCB;
a controller means mounted directly to the surface of the PCB between the first storage means and the second storage means and being communicatively coupled to the first storage means using the first signal means and being communicatively coupled to the second storage means using the second signal means; and
a covering means encapsulating the first storage means, the second storage means and the controller means.

17. The data storage device of claim 16, wherein the first storage means and the second storage means are comprised of NAND memory dies.

18. The data storage device of claim 16, further comprising one or more electronic components coupled to the surface of the PCB, wherein the one or more components are encapsulated by the covering means.

19. The data storage device of claim 16, wherein the controller means is communicatively coupled to a connection means of the data storage device.

20. The data storage device of claim 16, wherein the controller means is mounted directly to the surface of the PCB using a reflow soldering process.
